(19) United States
(12) Patent Application Publication
(10) Pub. No.: US 2015/0064880 A1
(43) Pub. Date: Mar. 5, 2015

(54) POST ETCH TREATMENT TECHNOLOGY FOR ENHANCING PLASMA-ETCHED SILICON SURFACE STABILITY IN AMBIENT

(71) Applicant: APPLIED MATERIALS, INC., Santa Clara, CA (US)

(72) Inventors: Jun Wan KIM, San Jose, CA (US); Hun Sang KIM, San Ramon, CA (US); Changhun LEE, San Jose, CA (US); Ho Jeong KIM, San Jose, CA (US); Yi ZHOU, Fremont, CA (US)

(21) Appl. No.: 14/015,780

(22) Filed: Aug. 30, 2013

(51) Int. Cl. H01L 21/322

(52) U.S. Cl. CPC H01L 21/322
USPC 438/474

(57) ABSTRACT

Methods for performing post etch treatments on silicon surfaces etched using halogen chemistry are provided. The methods may be performed in-situ a chamber in which the silicon surfaces where etch, ex-situ the chamber, or in a hybrid process that combines both in-situ and ex-situ post etch treatment processes. In one embodiment the post etch treatment process includes exposing a substrate having a silicon surface etched using halogen chemistry to a gas mixture comprising CₓH_{y} and oxygen, wherein x and y are integers, forming a plasma from the gas mixture, binding halogen residues with species comprising the plasma to form non-volatile halogen containing elements, and pumping the non-volatile halogen containing elements from a chamber containing the substrate.

### BACKGROUND OF THE INVENTION

1. Field

Embodiments of the present invention generally relate to a method and apparatus for post etch treatment technology of a substrate surface. More particularly, embodiments herein relate substrate surface passivation and improving substrate radical confinement after etching.

2. Description of Related Art

In the process of fabricating modern semiconductor integrated circuits (ICs), it is necessary to develop various material layers over previously formed layers and structures. Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The multilevel interconnects that lie at the heart of this technology require precise imaging and placement of high aspect ratio features, such as vias and other interconnects. Reliable formation of these interconnects is critical to further increases in device and interconnect density.

As the circuit densities increase for next generation devices, the width or pitch of interconnects, such as vias, trenches, contacts, devices, gates and other features, as well as the dielectric materials there between, are decreasing from 45 nm to sub 20 nm dimensions. The smaller circuit densities require etch process parameters to be held to smaller tolerances and for contamination introduced into the etch process environment, as well as the surface of the substrate, to be minimized. Generally, a conventional hydrogen (H)-comprising post-etch treatment is used for making the semiconductor substrate surface stable in ambient conditions to prevent the off gassing of residual halogens which then contaminate the fabrication process. However, the conventional H-comprising post etch treatment do not provide enough surface treatment and induces condensed particles which accumulate on the semiconductor substrate surface during the ambient temperature wait time between processes. Defects are formed on the semiconductor substrate surface by the highly corrosive halogen by-products (condensed particles) which formed in the ambient conditions. Moreover, prolonged exposure from the highly corrosive halogens erodes a chamber process kits

Therefore, there is a need for an improved post etch treatment method and apparatus.

### SUMMARY

Methods for performing post etch treatments on silicon surfaces etched using halogen chemistry are provided. The methods may be performed in-situ a chamber in which the silicon surfaces where etch, ex-situ the chamber, or in a hybrid process that combines both in-situ and ex-situ post etch treatment processes.

In one embodiment the post etch treatment process includes exposing a substrate having a silicon surface etched using halogen chemistry to a gas mixture comprising CₓH_{y} and oxygen, wherein x and y are integers, forming a plasma from the gas mixture, binding halogen residues with species comprising the plasma to form non-volatile halogen containing elements, and pumping the non-volatile halogen containing elements from a chamber containing the substrate.

In one embodiment the post etch treatment process includes performing a first portion of the post etch treatment in a chamber in which the silicon surfaces were etched using halogen chemistry and performing a second portion of the post etch treatment in a chamber different from the chamber in which the silicon surfaces were etched. The first portion of the post etch treatment includes exposing the silicon surfaces etched using halogen chemistry to a gas mixture comprising CₓH_{y} and oxygen, wherein x and y are integers, forming a plasma from the gas mixture, binding halogen residues with species comprising the plasma to form non-volatile halogen containing elements, and pumping the non-volatile halogen containing elements from the chamber containing the substrate. The second portion of the post etch treatment includes exposing the silicon surface to a gas mixture comprising CₓH_{y} and oxygen, wherein x and y are integers, forming a plasma from the gas mixture, binding halogen residues with species comprising the plasma to form non-volatile halogen containing elements, and pumping the non-volatile halogen containing elements from the chamber containing the substrate.

### BRIEF DESCRIPTION OF THE DRAWINGS

So that the manner in which the above recited embodiments of the invention are obtained and can be understood in detail, a more particular description of the invention, briefly summarized above, may be had by reference to the embodiments thereof, which are illustrated in the appended drawings. It is to be noted, however, that the appended drawings illustrate only typical embodiments of the invention, and are therefore not to be considered limiting of its scope, for the invention may admit to other equally effective embodiments.

FIG. 1 is a plan view of a semiconductor substrate processing system having an etch chamber and a load lock chamber;

FIG. 2 is a simplified cutaway view for the etch chamber of FIG. 1;

FIG. 3 is a simplified cutaway view of the load lock chamber depicted in FIG. 1; and

FIG. 4 is a block diagram of a method for a hybrid in-situ and ex-situ treatment of post etched substrates.

To facilitate understanding, identical reference numerals have been used, wherever possible, to designate identical elements that are common to the Figures. Additionally, elements of one embodiment may be advantageously adapted for utilization in other embodiments described herein.

### DETAILED DESCRIPTION

Disclosed are embodiments for a post etch treatment (PET) of a substrate using hydrocarbon (CH)-containing gas chemistries. Prolonged hydrogen exposure of a substrate, in conventional hydrogen (H)-comprising PET processes, increases the erosion of process kits and particle generation on and around the substrate. Replacing the conventional H-comprising PET with CH-containing PET extends the process kit lifetime and better controls condensed particles. The CH comprising PET has shown better condensed particle control than conventional H-comprising PET over a prolong period of time. Tests have demonstrated that after 24 hours at ambient temperatures, the conventional H-comprising PET surfaces increasingly accumulates condensed particle while the CH-containing PET surfaces remain relatively stable with minimal accumulation of condensed particles. Additionally, CH-containing PET surfaces have lower halogen residue concentrations for F, Cl, and Br compared to the conventional H-comprising PET surfaces. It is believed that the conventional H-comprising PET allows unstable bonds at the surface to interact at the ambient temperatures. However, CH-containing PET formed a thin carbon passivation layer on the surface for the substrate, thereby preventing the reactions at the ambient temperatures.

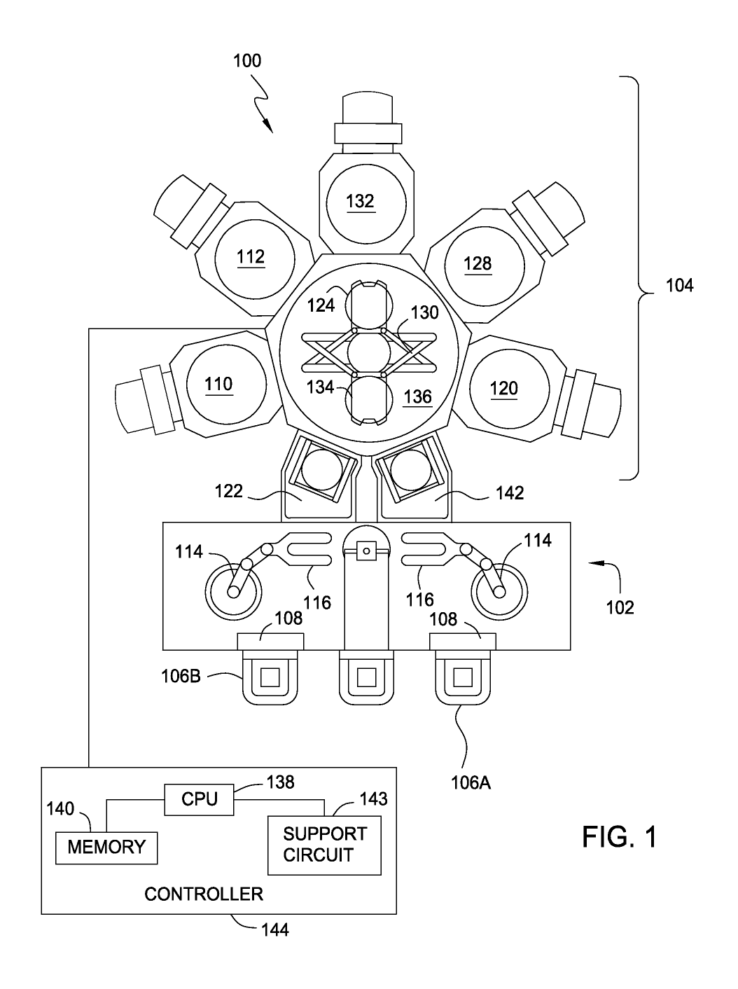

FIG. 1 is a plan view of a semiconductor substrate processing system 100 having an etch chamber and a load lock chamber. The processing system 100 is suited for performing a CH-containing PET after an etch process. In one embodiment, the processing system 100 may be a suitably adapted CENTURA® integrated processing system, commercially available from Applied Materials, Inc., located in Santa Clara, Calif. It is contemplated that the CH-containing PET may be practiced in other processing systems, including those from other manufacturers.

The processing system 100 includes a vacuum-tight processing platform 104, a factory interface 102, and a system controller 144. The processing platform 104 includes a plurality of processing chambers 110, 112, 132, 128, 120 and at least one load-lock chamber 142 that are coupled to a vacuum substrate transfer chamber 136. Two load lock chambers 122, 142 are shown in FIG. 1. The factory interface 102 is coupled to the transfer chamber 136 by the load lock chambers 122, 142.

In one embodiment, the factory interface 102 comprises at least one docking station 108 and at least one factory interface robot 114 to facilitate transfer of substrates. The docking station 108 is configured to accept one or more front opening unified pod (FOUP). Two FOUPS 106A-B are shown in the embodiment of FIG. 1. The factory interface robot 114, having a blade 116 disposed on one end of the factory interface robot 114, is configured to transfer the substrate to and from the factory interface 102 to the load lock chambers 122, 142 of the processing platform 104.

Each of the load lock chambers 122, 142 have a first port coupled to the factory interface 102 and a second port coupled to the transfer chamber 136. The load lock chambers 122 are coupled to a pressure control system (not shown) which pumps down and vents the load lock chambers 122, 142 to facilitate passing the substrate between the vacuum environment of the transfer chamber 136 and the substantially ambient (e.g., atmospheric) environment of the factory interface 102.

The transfer chamber 136 has a vacuum robot 130 disposed therein. The vacuum robot 130 has at least one blade 134 capable of transferring substrates 124 between the load lock chambers 122, 142 and the processing chambers 110, 112, 132, 128, 120.

In one embodiment, at least one process chamber 110, 112, 132, 128, 120 is an etch chamber. For example, the process chamber 110 may be an AdvantEdge Mesa™ etch chamber available from Applied Materials, Inc. The processing chamber 110 may use a halogen-containing gas to etch the substrate 124 disposed therein. Examples of halogen-containing gas include hydrogen bromide (HBr), chlorine (Cl₂), carbon tetrafluoride (CF₄), and the like.

The system controller 144 is coupled to the processing system 100. The system controller 144 controls the operation of the processing system 100 using a direct control of the processing chambers 110, 112, 132, 128, 120 of the processing system 100 or alternatively, by controlling the computers (or controllers) associated with the processing chambers 110, 112, 132, 128, 120 and the processing system 100. In operation, the system controller 144 enables data collection and feedback from the respective chambers and system controller 144 to optimize performance of the processing system 100.

The system controller 144 generally includes a central processing unit (CPU) 138, a memory 140, and support circuits 143. The CPU 138 may be one of any form of a general purpose computer processor that can be used in an industrial setting. The support circuits 143 are conventionally coupled to the CPU 138 and may comprise cache, clock circuits, input/output subsystems, power supplies, and the like. The software routines when executed by the CPU 138, transform the CPU 138 into a specific purpose computer (controller) 144. The software routines may also be stored in and/or executed by a second controller (not shown) that is located remotely from the processing system 100.

It has been known that prolonged hydrogen exposure may increase erosion of process kits and increase particle contamination of the substrate 124 and the processing system 100. In one embodiment the substrate 124 is loading by the factory interface robot 114 into the load lock chamber 122 from the FOUP 106B. A vacuum robot 130 moves the substrate 124 into the processing chamber 110 for etching. After etching, the substrate 124 is subject to a CH-containing post etch treatment. The CH-containing PET helps to extend the process kit lifetime and better control condensation of particles within the chamber 110. In one embodiment, the CH-containing PET uses a CₓH_{y} gas chemistry where x and y are integers. The CH-containing PET removes etchant and other particles from the surface of the etched substrate which may undesirably contaminate the environment of the processing system 100. The CH-containing PET may be performed in-situ, for example in the processing chamber 110 in which the substrate was etched, or ex-situ the processing chamber 110, for example in the load lock chamber 142 or transfer chamber 136. Alternately, the CH-containing PET may be a hybrid operation wherein part of the operation takes place in-situ while another part of the hybrid operation is performed ex-situ the processing chamber 110.

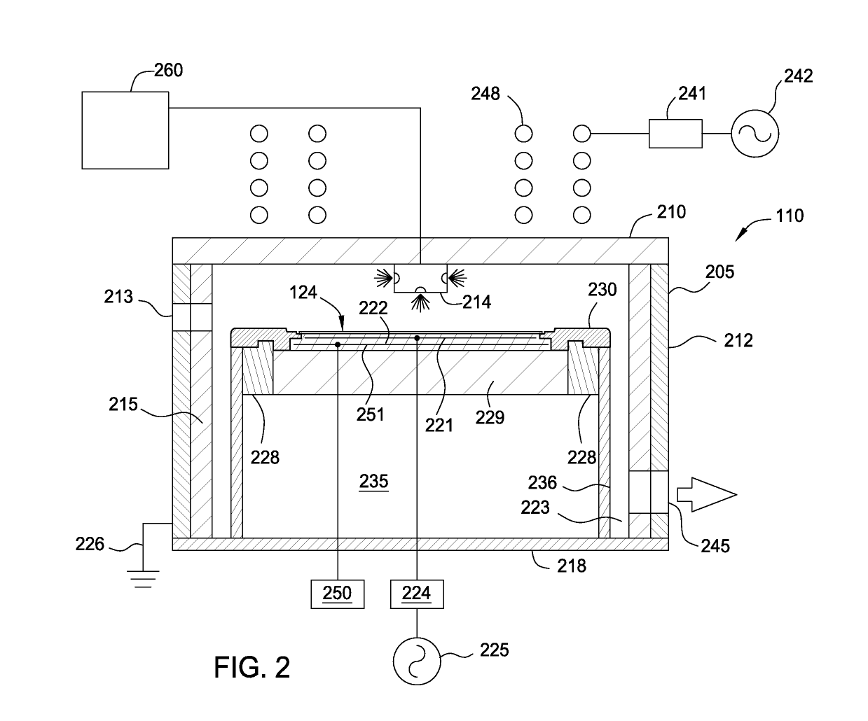

The CH-containing PET carried out in the same process chamber at the end of the plasma etch is herein after referred to as “in-situ PET.” The in-situ PET is performed after the etch process in the same chamber in where the substrate was etched. The CH-containing PET utilizes a plasma source gas comprising a CₓH_{y} gas chemistry, wherein x and y are integers. The plasma source gas may also include oxygen and at least one noble gas or inert gas, such as argon (Ar) or helium (He). The in-situ PET reduces the overall process time for processing a substrate by eliminating the transfer of the substrate to another chamber for a PET process and any additional time for chamber pumping. FIG. 2 illustrates an exemplary etch processing chamber 110 for performing in-situ PET.

The exemplary processing chamber 110 is configured as an etch processing chamber and is suitable for removing one or more material layers from a substrate and performing post etch treatment on a substrate 124. One example of the process chamber that may be adapted to benefit from the invention is an AdvantEdge Mesa™ Etch processing chamber, available from Applied Materials, Inc., located in Santa Clara, Calif. It is contemplated that other etch chambers, including those from other manufactures, may be adapted to practice embodiments of the invention.

The processing chamber 110 includes a chamber body 205 having a processing volume defined therein. The chamber body 205 has sidewalls 212 and a bottom 218 and a ground shield assembly 226 coupled thereto. The sidewalls 212 have a liner 215 to protect the sidewalls 212 and extend the time between maintenance cycles of the processing chamber 110. The dimensions of the chamber body 205 and related components of the processing chamber 110 are not limited and generally are proportionally larger than the size of the substrate 124 to be processed therein. Examples of substrate sizes include 200 mm diameter, 250 mm diameter, 300 mm diameter and 450 mm diameters, among others.

A chamber lid assembly 210 is mounted on the top of the chamber body 205. The chamber body 205 may be fabricated from aluminum or other suitable materials. A substrate access port 213 is formed through the sidewall 212 of the chamber body 205, facilitating the transfer of the substrate 124 into and out of the processing chamber 110. The access port 213 may be coupled to a transfer chamber and/or other chambers of the substrate processing system 100 (as shown in FIG. 1).

A pumping port 245 is formed through the sidewall 212 of the chamber body 205 and connected to the chamber volume through the exhaust manifold 223. A pumping device (not shown) is coupled through the port 245 to the processing volume to evacuate and control the pressure therein. The pumping device may include one or more pumps and throttle valves. The pumping device and chamber cooling design enables high base vacuum (about 1×E⁻⁸ Torr or less) and low rate-of-rise (about 1,000 mTorr/min) at temperatures suited to thermal budget needs for etching and post etch treatment, e.g., about −25 degrees Celsius to about +500 degrees Celsius.

A gas source 260 is coupled to the chamber body 205 to supply process gases into the processing volume. In one or more embodiments, process gases includes at least one halogen containing gas, and may additionally include inert gases, non-reactive gases, and reactive gases if necessary. Examples of process gases that may be provided by the gas source 260 include, but not limited to, carbon tetrafluoride (CF₄), hydrogen bromide (HBr), hydrogen fluoride (HF), acetylene (C₂H₄), methane (CH₄), argon gas (Ar), chlorine (Cl₂), nitrogen (N₂), oxygen gas (O₂), among others. Additionally, combinations of the gases may be supplied to the chamber body 205 from the gas source 260. For instance, a mixture of HBr and O₂ may be supplied into the processing volume to etch an aluminum (Al) containing substrate. The gas source 260 may also provide process gasses for the in-situ PET. For example the process gas supplied by the gas source 260 for PET of the substrate 124 may include a mixture of H₂, O₂ and N₂; O₂ and N₂; Ar and O₂; or CH₄ and O₂, among others. In one embodiment, the gas source 260 provides CH₄ and O₂ into the chamber body 205 for PET of a substrate 124 to reduce halogen byproduct formation.

The lid assembly 210 may include a nozzle 214. The nozzle 214 has one or more ports for introducing process gas from the gas source 260 into the processing volume. After the process gas is introduced into the processing chamber 110, the gas is energized to form plasma. An antenna 248, such as one or more inductor coils, may be provided adjacent to the processing chamber 110. An antenna power supply 242 may power the antenna 248 through a match circuit 241 to inductively couple energy, such as RF energy, to the process gas to maintain a plasma formed from the process gas in the processing volume within the processing chamber 110. Alternatively, or in addition to the antenna power supply 242, process electrodes comprising a cathode below the substrate 124 and an anode above the substrate 124 may be used to capacitively couple RF power to the process gases to maintain the plasma within the processing volume. A controller may control the operation of the power supply 242 and also the operation of other components in the processing chamber 110.

A substrate support pedestal 235 may include an electro-static chuck 222 for holding the substrate 124 during processing. The electro-static chuck (ESC) 222 uses the electro-static attraction to hold the substrate 124 to the substrate support pedestal 235 for an etching process. The ESC 222 is powered by an RF power supply 225 integrated with a match circuit 224. The ESC 222 comprises an electrode 221 embedded within a dielectric body. The RF power supply 225 may provide a RF chucking voltage of about 200 volts to about 2000 volts to the electrode 221. The RF power supply 225 may also include a system controller for controlling the operation of the electrode 221 by directing a DC current to the electrode 221 for chucking and de-chucking the substrate 124. The ESC 222 has an isolator 228 for the purpose of making the sidewall of the ESC 222 less attractive to the plasma. Additionally, the substrate support pedestal 235 has a cathode liner 236 to protect the sidewalls of the substrate support pedestal 235 from the plasma gasses and to extend the time between maintenance of the plasma processing chamber 110. The cathode liner 236 and the liner 215 may be formed from a ceramic material. For example, both the cathode liner 236 and liner 215 may be formed from Yttria.

The ESC 222 may include heaters 251, disposed therein and connected to a power source 250, for heating the substrate. The cooling base 229 may include conduits for circulating a heat transfer fluid to sinking heat from the ESC 222 and substrate 124 disposed thereon. The ESC 222 is configured to perform in the temperature range required by the thermal budget of the device being fabricated on the substrate 124. For example, the ESC 222 may be configured to maintain the substrate 124 at a temperature of about minus about 25 degrees Celsius to about 500 degrees Celsius. The cooling base 229 is provided to protect the substrate support pedestal 235 and assists in controlling the temperature of the substrate 124. For example, the temperature of the substrate 124 in the etch processing chamber 110 is about 70 degrees Celsius to about 88 degrees Celsius for the etch process and the PET process. To mitigate process drift and time, the temperature of the substrate 124 is maintained substantially constant throughout the time the substrate 124 is in the etch chamber. In one embodiment, the temperature of the substrate 124 is maintained throughout the etch process and the PET process at about 80 degrees Celsius.

A cover ring 230 is disposed on the ESC 222 and along the periphery of the substrate support pedestal 235. The cover ring 230 is configured to confine etching gases to a desired portion of the exposed top surface of the substrate 124, while shielding the top surface of the substrate support pedestal 235 from the plasma environment inside the processing chamber 200. Lift pins (not shown) are selectively moved through the substrate support pedestal 235 to lift the substrate 124 above the substrate support pedestal 235 to facilitate access to the substrate 124 by a vacuum robot 130 (shown in FIG. 1) or other suitable transfer mechanism.

A system controller 144 (shown in FIG. 1) may be coupled to the processing chamber 110. The system controller 144 may be utilized to control the process sequence, regulating the gas flows from the gas source 260 into the processing chamber 110 and other process parameters. Software routines, when executed by the CPU 138, transform the CPU 138 into a specific purpose computer (controller) that controls the processing chamber 110 such that the processes are performed in accordance with the present invention. The software routines may also be stored in memory 140 and/or executed by a second controller (not shown) that is collocated with the processing chamber 110.

The in-situ PET provides a high throughput for an integrated etch recipe and reduces the time between completing the etching process and the surface treatment for the substrate 124 by combining the steps in one chamber. In addition, “in-situ” PET may also be used as a de-chunking step. The in-situ PET enables a shorter in-situ chamber clean (ICC) time which enhances the throughput for the processing chamber 110 and prolongs the lifetime of the process kits.

The off gassing halogens from an etched surface of the substrate 124 may condensate to form particle contamination. The PET stabilizes the surface of the substrate 124 to abate the off gassing halogens and the particles formed by condensing of the gasses at ambient temperatures. The condensed particle (adders) counts are checked to determine the success of a PET recipe. In one embodiment, the particle adder count for a substrate 124 is less than about 10 adders after the post etch treated substrate 124 is held for about 24 hours in a closed FOUP.

The abatement for various etchants may have different PET recipe strategies. Example combinations for PET gasses may include hydrogen (H₂), oxygen (O₂) and nitrogen (N₂); O₂ and N₂; argon (Ar) and O₂; or methane (CH₄) and O₂; to name a few. Additionally, the recipe for the PET gasses may call for the gasses to be applied over a specified period of time, for example, about 10 seconds to about 30 seconds. The different gases used in the PET processes may be selected in response to the different enchants used in the etch processing chamber 110. In one embodiment, halogen abatement may be performed in-situ with the combination of oxygen (O₂) and CH-containing PET. Meanwhile, chlorine (Cl) abatement may be performed in-situ with O₂ and CH-containing PET gasses, and additionally carried out over a long period of time, for example about 20 seconds.

In certain embodiments, after etching the surface of the substrate 124 in an etch processing chamber 110, a post-etch treatment is performed in-situ, in the processing chamber 110. The processing chamber 110 vacuum pressures may be maintained at about 20 mT and the bias power removed from the substrate 124 to prevent further etching of the surface of the substrate 124. A process gas is introduced by the gas source 260.

In one embodiment, the gas source 260 provides about 50 sccm of H₂, about 200 sccm of O₂, and about 50 sccm of N₂ into the processing chamber 110 to form the process gas mixture. About 1000 Watts of RF power is provided to the antenna 248 to form plasma from the process gas mixture. For about 20 seconds, the reactive specifies from the plasma treats the surface of the substrate 124 and other surfaces within the processing chamber 110.

In another embodiment, the gas source 260 provides about 5 sccm of CH₄, and about 200 sccm of O₂ into the processing chamber 110 to form the process gas mixture. About 1000 Watts of RF power is provided to the antenna 248 to form plasma from the process gas mixture. For about 20 seconds, the reactive specifies from the plasma treats the surface of the substrate 124 and other surfaces within the processing chamber 110.

In yet another embodiment, the gas source 260 provides about 200 sccm of O₂, and about 50 sccm of N₂ into the processing chamber 110 to form the process gas mixture. About 1000 Watts of RF power is provided to the antenna 248 to form plasma from the process gas mixture. For about 20 seconds, the reactive specifies from the plasma treats the surface of the substrate 124 and other surfaces within the processing chamber 110.

In yet another embodiment, the gas source 260 provides about 100 sccm of Ar and about 200 sccm of O₂ into the processing chamber 110 to form the process gas mixture. About 1000 Watts of RF power is provided to the antenna 248 to form plasma from the process gas mixture. For about 20 seconds, the reactive specifies from the plasma treats the surface of the substrate 124 and other surfaces within the processing chamber 110.

The process gas stabilizes the surface of the substrate 124 and reduces the off gassing of halogens from the surface of the substrate 124 and byproducts forming on the substrate or the surfaces of the processing chamber 110

Alternatively the PET may be carried out in a different processing chamber from which the substrate 124 was etched. The PET operation performed external to the processing chamber 110 in which the substrate 124 was etched is referred to as ex-situ PET. Ex-situ PET allows for the usage of a high pedestal temperature compared to the in-situ PET process which provides improved halogen abatement. In one embodiment, the ex-situ PET may be performed in a load lock chamber to remove volatile halogen residues from the surface of the substrate 124.

Referring briefly back to FIG. 1, the factory interface 102 is coupled to the transfer chamber 136 by the load lock chambers 122, 142. The vacuum robot 130 transfers the substrate 124 from the processing chamber 110 through the load lock chamber 142 to the factory interface 102. The load lock chamber 142 has a chamber body 340 with openings 360 configured to allow the substrate 124 to enter and exit the load lock chamber 142.

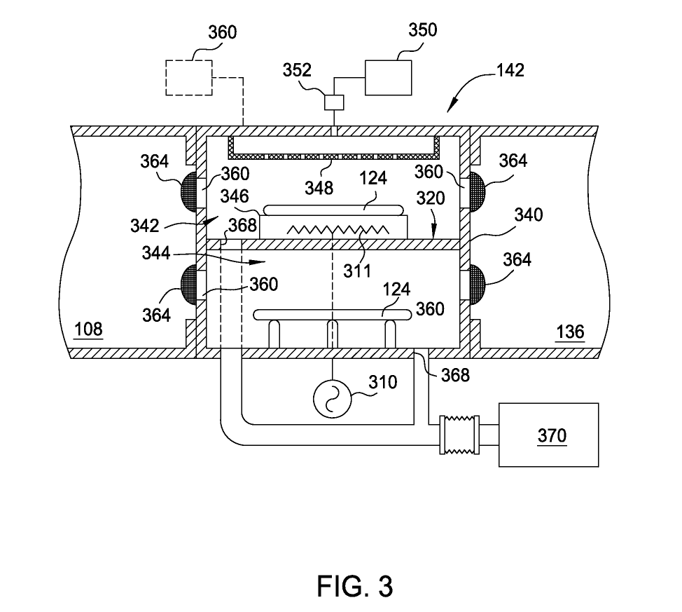

FIG. 3 depicts a simplified cutaway view for the load lock chamber 142 configured to perform ex-situ PET. The chamber body 340, of the load lock 142 chamber, has a first chamber 342 and a second chamber 344 defined therein. The first chamber 342 is isolated from the second chamber 344 by a wall 320 such that the pressure within the chambers 342, 344 may be independently controlled. The first chamber 342, shown in the embodiment depicted in FIG. 3 stacked above the second chamber 344, is configured to not only transfer substrates between the factory interface 102 and transfer chamber 136, but also to perform a post etch treatment process.

In the embodiment depicted in FIG. 3, the first chamber 342 includes a heater 311 coupled to a power source 310. The heater 311 is configured for heating a substrate support pedestal 346. The substrate support pedestal 346 is disposed below a gas distribution plate 348. A gas panel 350 is coupled to the first chamber 342 through a remote plasma source 352 such that reactive specifies from a processing gas may be provided into the first chamber 342 through the gas distribution plate 348 to process the substrate 124 disposed on the heated substrate support pedestal 346. The gas panel 350 may also be configured to provide a purged gas.

A pumping port 368 is connected to the first chamber 342 and second chamber 344. A slit valve door 364 opens and closes access through the openings 360. A pumping device 370, coupled to the volume of chambers 342, 344, may evacuate and control the pressure in the load lock chamber 142 once the slit valve door 364 has been closed. The pumping device 370 may include one or more pumps and throttle valves. The pumping device 370 enables high base vacuum of about 1×E⁻⁸ Torr or less.

The first chamber 342 may be utilized to pass substrates from the transfer chamber 136 to the factory interface 102, while the second chamber 344 may be solely utilized to have unprocessed substrates from the factory interface 102 into the transfer chamber 136, thereby minimizing the potential of cross contamination between processed and unprocessed substrates.

As previously stated, one advantage of the halogen-containing residue removal process is the usage of the high temperature substrate support pedestal 346 for halogen abatement. During the ex-situ PET the substrate support pedestal 346 may raise the temperature of the processed substrate, thereby converting the halogen-containing residues to a non-volatile compound. In one embodiment, the substrate support pedestal 346 raises the surface temperature of the substrate 124 to about 250 degrees Celsius to convert the halogen-containing residues to a non-volatile compound. The remote plasma source 352 provides reactive species which bind, or react, with the non-volatile compounds and/or halogen containing residues. The non-volatile compounds are then pumped out from the first chamber 342 of the load lock chamber 142 to remove effectively the halogens from the substrate 124 and components of the chamber 342.

The different gases used in the ex-situ PET processes may be selected in response to the different enchants used in the etch processing chamber 110. Examples of ex-situ PET process gas mixtures may include oxygen (O₂) and nitrogen (N₂); Forming Gas (FG) and O₂; or O₂, N₂ and water (H₂O); among others. FG may be a mixture of hydrogen and nitrogen. In one embodiment, the FG is about 1% to about 3% diluted H₂ in N₂. Additionally, the selection for the different ex-situ PET gasses may include the application of the process gasses over a specified period of time, for example, about 10 seconds to about 30 seconds.

Etch chambers may use a halogen-containing gas to etch the substrates therein. Examples of halogen-containing gas include hydrogen bromide (HBr), chlorine (Cl₂), carbon tetrafluoride (CF₄), and the like. Fluorine (F), chlorine (Cl), and bromine (Br) abatement may be performed ex-situ with the combination of oxygen (O₂) and nitrogen (N₂) containing gasses along with a high substrate 124 temperature of about 250 degrees Celsius.

In certain embodiments, at least one of the process chambers coupled to the transfer chamber 136 is an etch chamber. After etching the substrate, halogen-containing residues may be left on the substrate 124 surface. The vacuum robot moves the substrate 124 to the first chamber 342 of the load lock chamber 142. The first chamber 342 performs ex-situ PET on the substrate 124. The heater 311 in the first chamber 342 heats the substrate 124 to about 250 degrees Celsius, under a vacuum pressure of about 700 mT.

In one embodiment, the gas panel 350 provides 3500 sccm of O₂, and 350 sccm of N₂ through the remote plasma source 352 to form a process gas mixture. About 5000 Watts of RF power is provided to the remote plasma source 352 to form plasma from the process gas mixture. The plasma reactive specifies may treat the surface of the substrate 124 for about 20 seconds.

In another embodiment, the gas panel 350 provides 2500 sccm of O₂, 250 sccm of N₂, and 500 sccm of H₂O through the remote plasma source 352 to form a process gas mixture. About 5000 Watts of RF power is provided to the remote plasma source 352 to form plasma from the process gas mixture. The plasma reactive specifies may treat the surface of the substrate 124 for about 20 seconds.

In yet another embodiment, the gas panel 350 provides 2500 sccm of O₂ and 500 sccm of FG through the remote plasma source 352 to form a process gas mixture. About 5000 Watts of RF power is provided to the remote plasma source 352 to form plasma from the process gas mixture. The plasma reactive specifies may treat the surface of the substrate 124 for about 20 seconds.

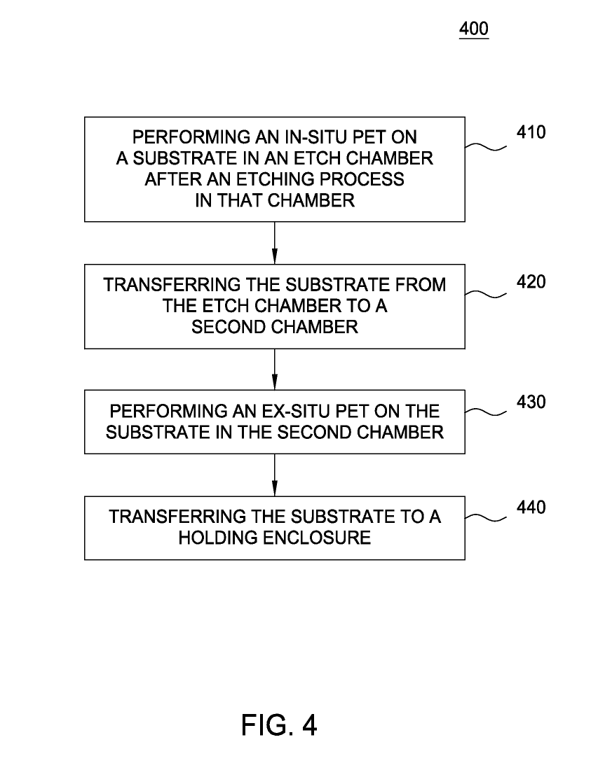

Although the first chamber 342 of the load lock chamber 142 has been described as configured to perform an ex-situ PET process, it is contemplated that the method of performing a PET of the substrate 124 may be also be a hybrid method wherein the PET process may be performed both in-situ and ex-situ. FIG. 4 illustrates a method 400 for a hybrid in-situ and ex-situ treatment of post etched substrates. Steps in the method provide in-situ and ex-situ recipes which compliment and work in relationship with each other. It should be noted that the combination of the in-situ PET and ex-situ PET in the hybrid PET may have results that contrast to than that of in-situ PET or ex-situ PET performed alone.

At block 410, an in-situ PET is performed on a substrate. After completing an etching process, the substrate remains in the etch chamber for further processing. The etch chamber may be similar to processing chamber 110 as shown in FIG. 2. The in-situ PET process performed in the etch chamber is performed in consideration of further treatment ex-situ.

In one embodiment, after etching the surface of the substrate in the etch processing chamber, the first portion of the hybrid PET is performed in-situ. The processing chamber vacuum pressures may be maintained at about 20 mT and the bias power removed from the substrate to prevent further etching of the substrate surface. A process gas is introduced by the gas source. The gas source provides about 200 sccm of O₂, and about 50 sccm of N₂ into the processing chamber to form the process gas mixture. About 1000 Watts of RF power is provided to the antenna to form plasma from the process gas mixture. For about 20 seconds, the plasma reactive specifies may treat the substrate surface and additionally the process chamber.

In another embodiment, the in-situ portion of the hybrid PET is performed in the processing chamber with vacuum pressures of about 20 mT and the bias power turned off to prevent further etching of the substrate surface. The gas source provides about 5 sccm of CH₄, and about 200 sccm of O₂ into the processing chamber to form the process gas mixture. About 1000 Watts of RF power is provided to the antenna to form plasma from the process gas mixture. For about 20 seconds, the plasma may treat the substrate surface and the process chamber to effectively remove halogen contamination.

At block 420, the substrate is transferred from the etch processing chamber to a second chamber. The vacuum robot may transfer the substrate from the etch processing chamber into the second chamber. The second chamber is configured to perform the second ex-situ PET portion of the hybrid PET.

At block 430, the ex-situ PET is performed on the substrate in the second processing chamber. The second processing chamber may be a second etch chamber, a load lock chamber, or other chamber configured to perform the ex-situ PET process. In one embodiment, the second processing chamber is the load lock chamber 142. In another embodiment, the second processing chamber is an etch chamber. The second ex-situ PET portion of the hybrid PET is complimentary to the in-situ PET portion of the hybrid PET already performed on the substrate. The process for the second ex-situ PET portion of the hybrid PET may differ from that of a “stand alone” ex-situ PET process, wherein the substrate has not already been treated in-situ.

In one embodiment, the second ex-situ PET portion of the hybrid PET process is performed at a vacuum pressure which may be about 700 mT while the substrate surface is heated to about 250 degrees Celsius. The gas source provides about 3500 sccm of O₂, and about 350 sccm of N₂ into the processing chamber to form the process gas mixture. About 5000 Watts of RF power is provided to the antenna to form plasma from the process gas mixture. For about 20 seconds, the plasma reactive specifies and heat may treat the substrate surface to effectively remove halogen contamination.

At block 440, the substrate is transferred from the second processing chamber and eventually returned to the front opening unified pod (FOUP). The FOUP may hold a number of treated substrates. It has been demonstrated that substrates which have been treated as described above have less than about 10 additional particles condensed thereon after 24 hours when returned to the FOUP.

In one embodiment the hybrid PET has been shown to reduce the condensed particle formation to less than about 5 particles per substrate over 24 hours. The in-situ PET is performed in the etch chamber under a vacuum pressure of about 20 mT with the bias power removed from the substrate to prevent further etching of the substrate surface. The gas source provides about 5 sccm of CH₄, and about 200 sccm of O₂ into the processing chamber to form the process gas mixture. About 1000 Watts of RF power is provided to the antenna to form plasma from the process gas mixture. For about 20 seconds, the plasma reactive specifies may treat the substrate surface and the process chamber. The substrate is moved to a second chamber wherein the processing chamber vacuum pressure may be about 700 mT and the substrate surface is heated to about 250 degrees Celsius. A process gas is introduced by the gas source. The gas source provides about 3500 sccm of O₂, and about 350 sccm of N₂ into the processing chamber to form the process gas mixture. About 5000 Watts of RF power is provided to the antenna to form plasma from the process gas mixture. For about 10 seconds, the plasma reactive specifies and heat may treat the substrate surface.

In-situ PET, ex-situ PET and a hybrid PET, each represents a significant advancement in the field of substrate surface passivation and improving substrate radical confinement after etching. Moreover, condensed particle counts, are significantly reduced compared to conventional post etch treatment processes.

While the foregoing is directed to embodiments of the present invention, other and further embodiments of the invention may be devised without departing from the basic scope thereof, and the scope thereof is determined by the claims that follow:

What is claimed is:

1. A post etch treatment for silicon surfaces etched using halogen chemistry, the post etch treatment comprising:
exposing a substrate having a silicon surface etched using halogen chemistry to a gas mixture comprising CₓH_{y} and oxygen, wherein x and y are integers;
forming a plasma from the gas mixture;
binding halogen residues with species comprising the plasma to form non-volatile halogen containing elements; and
pumping the non-volatile halogen containing elements from a chamber containing the substrate.

2. The post etch treatment of claim 1, wherein exposing comprises:
exposing the substrate to the gas mixture within the chamber in which the silicon surface was etched.

3. The post etch treatment of claim 1 further comprising:
transferring the substrate into the chamber from an etch chamber in which the silicon surface was etched.

4. The post etch treatment of claim 1 further comprising:
venting the chamber to substantially atmospheric pressure; and
transferring the substrate to a factory interface.

5. The post etch treatment of claim 1 further comprising:
maintaining the substrate at a temperature equal to about a temperature at which the silicon surface was etched.

6. The post etch treatment of claim 1 further comprising:
maintaining the substrate at a temperature above a temperature at which the silicon surface was etched.

7. The post etch treatment of claim 1 further comprising:
maintaining a pressure within the chamber at about 20 mT to about 700 mT.

8. The post etch treatment of claim 1 further comprising:
maintaining the plasma within the chamber with no bias power applied to the substrate.

9. The post etch treatment of claim 1, wherein exposing comprises:
providing CₓH_{y} gas at a rate of about 5 sccm.

10. The post etch treatment of claim 9, wherein the CₓH_{y} gas is CH₄.

11. The post etch treatment of claim 1, wherein exposing comprises:
providing oxygen gas at a rate of about 200 sccm to about 3500 sccm.

12. The post etch treatment of claim 1, wherein exposing comprises:
providing at least one of a noble gas or an inert gas with the gas mixture.

13. The post etch treatment of claim 12, wherein the inert gas is one of N₂, Ar and He.

14. The post etch treatment of claim 1, wherein forming the plasma from the gas mixture comprises:
inductively coupling about 1000 Watts to about 5000 Watts of power to one or more coils disposed proximate the chamber.

15. The post etch treatment of claim 1, wherein forming the plasma from the gas mixture comprises:
flowing the gas mixture through a remote plasma source.

16. The post etch treatment of claim 2 further comprising:
transferring the substrate into a second chamber; and
performing a second post etch treatment on the silicon surface.

17. A post etch treatment for silicon surfaces etched using halogen chemistry, the post etch treatment comprising:
A) performing a first portion of the post etch treatment in a chamber in which the silicon surfaces were etched using halogen chemistry, the first portion comprising:
exposing the silicon surfaces etched using halogen chemistry to a gas mixture comprising CₓH_{y} and oxygen, wherein x and y are integers;
forming a plasma from the gas mixture;
binding halogen residues with species comprising the plasma to form non-volatile halogen containing elements; and
pumping the non-volatile halogen containing elements from the chamber containing the substrate; and
B) performing a second portion of the post etch treatment in a chamber different from the chamber in which the silicon surfaces were etched, the second portion comprising:
exposing the silicon surface to a gas mixture comprising CₓH_{y} and oxygen, wherein x and y are integers;
forming a plasma from the gas mixture;
binding halogen residues with species comprising the plasma to form non-volatile halogen containing elements; and
pumping the non-volatile halogen containing elements from the chamber containing the substrate.

18. The post etch treatment of claim 17 further comprising:
maintaining the substrate at higher temperature during the second portion of the post etch treatment.

19. The post etch treatment of claim 17 further comprising:
maintaining the plasma within the chambers with no bias power applied to the substrate.

20. The post etch treatment of claim 1, wherein exposing during the first portion of the post etch treatment comprises:
providing CₓH_{y} gas at a rate of about 5 sccm; and
providing oxygen gas at a rate of about 200 sccm.
